(19) United States
(12) Patent Application Publication
(10) Pub. No.: US 2025/0201613 A1
(43) Pub. Date: Jun. 19, 2025

(54) SUBSTRATE TRANSFER ARM AND APPARATUS USING THE SAME

(71) Applicant: ASM IP Holding B.V., Almere (NL)

(72) Inventors: Yuki Dammura, Yamato-shi (JP); Masaei Suwada, Nagaoka-shi (JP)

(21) Appl. No.: 18/975,928

(22) Filed: Dec. 10, 2024

Related U.S. Application Data
(60) Provisional application No. 63/609,727, filed on Dec. 13, 2023.

(51) Int. Cl. H01L 21/677; H01L 21/67; H01L 21/687

(52) U.S. Cl. CPC H01L 21/67742; H01L 21/68707; H01L 21/67155

(57) ABSTRACT

Provided is a substrate transfer arm, more particularly to a substrate transfer arm to prevent the substrate from sticking thereto and reduce contaminants between the substrate transfer arm the substrate during moving the substrate transfer arm. In one or more embodiment, the substrate transfer arm may be provided with a body unit, a plurality of substrate mounting units coupled to the body, wherein the each of the substrate mounting units comprises a stopping unit and a pad unit coupled to the body unit, and the pad unit is tilted toward a first direction with respect to the body unit.

### CROSS-REFERENCE TO RELATED APPLICATION(S)

This application claims the benefit of U.S. Provisional Application 63/609,727 filed on Dec. 13, 2023, the entire contents of which are incorporated herein by reference.

### FIELD OF INVENTION

The disclosure relates to a substrate transfer arm and apparatus using the same, more particularly to a substrate transfer arm to prevent a substrate from sticking thereto and reduce particles generated during a movement of a substrate.

### BACKGROUND OF THE DISCLOSURE

A substrate transfer arm transfers a substrate into a reaction chamber from a substrate handling chamber of a substrate processing cluster tool or vice versa, or the substrate transfer arm transfers a substrate between reaction chambers in multi-reaction chamber, or the substrate transfer arm transfers a substrate from a substrate storage stage (e.g., a front opening unified pod (FOUP)) to a load lock chamber or vice versa in a substrate transport chamber (e.g., an equipment front end module (EFEM)).

FIG. 1A illustrates an existing substrate transfer arm and FIG. 1B illustrates a cross-sectional view of the substrate transfer arm of FIG. 1A with the substrate loaded.

In FIG. 1A, the substrate transfer arm 100 may comprise a body unit 101, a stopping unit 102, a pad unit 103 and a clamp unit 104 to clamp the substrate 106 to assist the substrate 106 to sit on the substrate transfer arm 100.

In FIG. 1B, when the substrate 106 is loaded on the substrate transfer arm 100, an edge of the substrate 106 may sit on the sloped upper surface 105 of the pad unit 103. The edge of the substrate 106 may slide on the upper surface 105 of the pad unit 103 and be positioned. The pad unit 103 may be formed of plastics such as glass carbon.

The method of loading the substrate 106 on the substrate transfer arm 100 according to FIG. 1B (i.e., an edge contact method), however, may generate contaminants such as particles due to friction between the edge of the substrate 106 and the upper surface 105 of the pad unit 103.

In the edge contact method, the substrate 106 may slide backward on the pad 103 unit when the clamp unit 104 unclamps the substrate 106. That may result in the substrate coming off the right loading position on a substrate support (not shown).

FIG. 2A illustrates another existing substrate transfer arm and FIG. 2B illustrates a cross-sectional view of the substrate transfer arm of FIG. 2A with the substrate loaded.

In FIG. 2B, when the substrate 106 is loaded on the substrate transfer arm 100, the substrate 106 may sit on the flat upper surface of the pad unit 107. The pad unit 107 may comprise plastics such as glass carbon and may be fixed to the body unit 101. As the upper surface of the pad unit 107 wears out due to a friction between the lower surface of the substrate 106 and the upper surface of the pad unit 107, the substrate may not slide around.

In the method of loading the substrate 106 on the substrate transfer arm 100 according to FIG. 2B (i.e., a backside contact method), the friction between the lower surface of the substrate 106 and the upper surface of the pad unit 107 may result in the substrate sticking and the generation of contaminants such as particles.

The substrate sticking to the substrate transfer arm 100 according to the backside contact method may further cause the substrate to come off the right loading position on the substrate support when being loaded on the substrate support (not shown herein).

### SUMMARY OF THE DISCLOSURE

The disclosure discloses a substrate transfer arm, more particularly to a substrate transfer arm to reduce contaminants between the substrate transfer arm and the substrate and to prevent the substrate from sticking to the substrate transfer arm.

In one or more embodiments, the substrate transfer arm may comprise a body unit and a plurality of substrate mounting units coupled to the body unit, wherein each of the substrate mounting units may comprise a stopping unit and a pad unit coupled to the body unit, and the pad unit may be tilted with respect to the body unit.

In one or more embodiments, the pad unit of the substrate transfer arm may be tilted between about 5° and about 30° with respect to the body.

In one or more embodiments, the pad unit may be tilted toward a first direction perpendicular to a moving direction of the substrate transfer arm.

In one or more embodiments, the pad unit may be tilted toward a second direction perpendicular to a moving direction of the substrate transfer arm, which is different from the first direction.

In one or more embodiments, the pad unit may comprise a rotatable unit, a support unit to support the rotatable unit and a fixing unit to fasten the rotatable unit to the support unit, wherein the support unit may be tilted with respect to the body unit.

In one or more embodiments, the rotatable unit may comprise a roller.

In one or more embodiments, an edge of the roller may be round.

In one or more embodiments, the rotatable unit may be formed of at least of cerazol, FFPM (Perfluorinated Elastomer), ceramic, a glass carbon, or a mixture thereof.

In one or more embodiments, the stopping unit may comprise a first portion and a second portion, and an inner side of the second portion may be tilted more than an inner side of the first portion with respected to the body.

In one or more embodiments, a horizontal cross-sectional width of the lower surface of the first portion may be wider than a horizontal cross-sectional width of the upper surface of the second portion.

In one or more embodiments, the stopping unit may further comprise a point in which the first portion and the second portion meet may be located at the height of the pad unit, or lower than the pad unit.

In one or more embodiments, the substrate transfer arm may further comprise a clamp unit to clamp the substrate.

### BRIEF DESCRIPTION OF THE DRAWING FIGURES

FIG. 1A illustrates an existing substrate transfer arm.

FIG. 1B illustrates a cross-sectional view of the substrate transfer arm of FIG. 1A with the substrate loaded.

FIG. 2A illustrates another existing substrate transfer arm.

FIG. 2B illustrates a cross-sectional view of the substrate transfer arm of FIG. 2A with the substrate loaded.

FIG. 3 illustrates a substrate transfer arm according to an embodiment of the present disclosure.

FIG. 4 illustrates a cross-sectional view of the pad unit.

FIG. 5 illustrates a cross-sectional view of the pad unit tilted with respect to the body unit of the substrate transfer arm according to an embodiment of the present disclosure.

FIG. 6A illustrates another embodiment of the pad unit.

FIG. 6B illustrates another embodiment of the pad unit.

FIG. 7 illustrates a cross sectional view of the substrate transfer arm along the cross-sectional line A-A′ of FIG. 3.

FIG. 8 illustrates the first direction perpendicular to a moving direction of the substrate transfer arm.

FIG. 9 illustrates a cross sectional view of another embodiment of the substrate transfer arm along the cross-sectional line A-A′ of FIG. 3.

FIG. 10 illustrates the second direction perpendicular to a moving direction of the substrate transfer arm.

FIG. 11 illustrates a cross-sectional view of an embodiment of a stopping unit coupled to the body unit of the substrate transfer arm along the cross-sectional line B-B′ of FIG. 3.

FIG. 12 illustrates a cross-sectional view of another embodiment of the stopping unit coupled to the body unit of the substrate transfer arm along the cross-sectional line B-B′ of FIG. 3.

FIG. 13 illustrates a configuration of a substrate processing cluster tool.

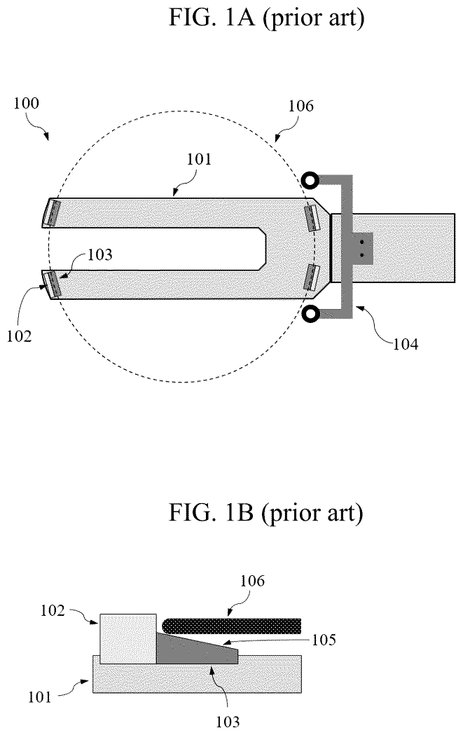

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particularly disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

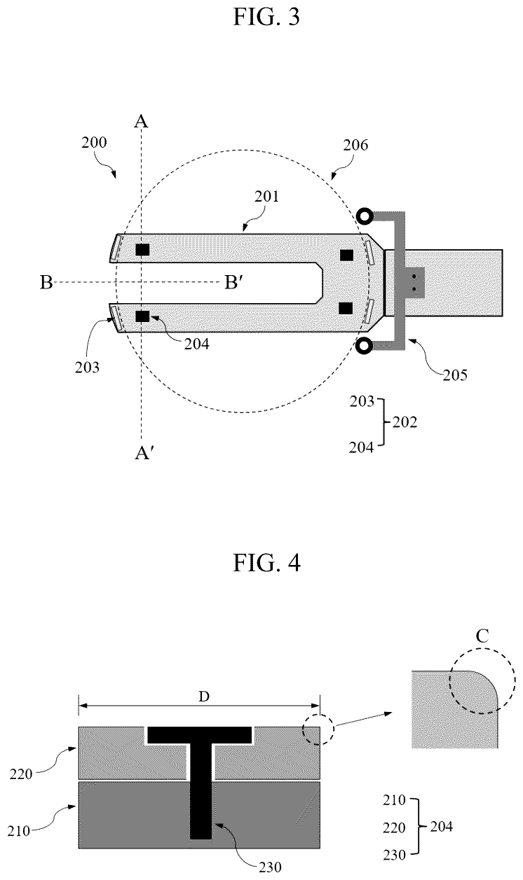

FIG. 3 illustrates a substrate transfer arm 200 according to an embodiment of the present disclosure.

In FIG. 3, the substrate transfer arm 200 may comprise a body unit 201 and a plurality of substrate mounting units 202. Each of the substrate mounting unit 202 may comprise a stopping unit 203 and a pad unit 204. The substrate 206 may be loaded on the pad unit 204. The stopping unit 203 may help with alignment and prevent the substrate 206 from being slid forward when loaded on the pad unit 204. The substrate transfer arm 200 may further comprise a clamp unit 205 to clamp the substrate 206. The clamp unit may assist the substrate 206 to sit on the substrate transfer arm 200.

FIG. 4 illustrates a cross-sectional view of the pad unit 204.

In FIG. 4, the pad unit 204 may comprise a rotatable unit 220, a support unit 210, and a fixing unit 230. In more detail, the rotatable unit 220 may be configured to rotate. The support unit 210 may support the rotatable unit 220. The fixing unit 230 may fasten the rotatable unit 220 to the support unit 210.

In an embodiment of the present disclosure, the rotatable unit 220 may be a roller and rotate. A diameter D of the roller 220 may be between about 0.8 cm and about 1.0 cm. The surface roughness of the roller 220 may be between about Ra 0.4 and about Ra 3.2. An edge of the roller 220 may be round, such that the roller 220 may have a curvature C between about Φ8 and about Φ10 at the edge.

The rotatable unit 220 may comprise at least one of cerazol, FFPM (Perfluorinated Elastomer), ceramic, a glass carbon, or a mixture thereof.

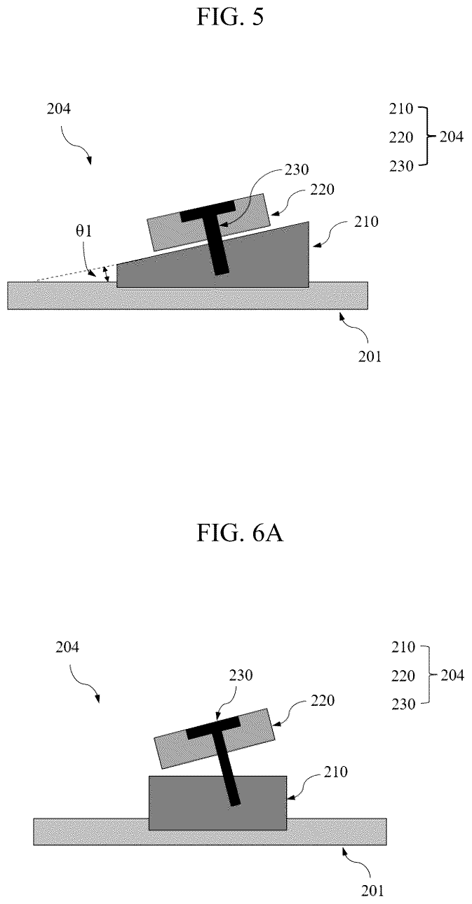

FIG. 5 illustrates a cross-sectional view of the pad unit 204 tilted with respected to the body unit 201 according to an embodiment of the present disclosure.

In FIG. 5, the support unit 210 may be designed to be tilted with respect to the body unit 201, and the rotatable unit 220 supported by the support unit 210 may be tilted with respect to the body unit 201 accordingly. In an embodiment of the present disclosure, the pad unit 204 may be tilted between about 5° and about 30° (01) with respect to the body unit 201.

FIG. 6A illustrates another embodiment of the pad unit 204. In FIG. 6A, the support unit 210 may be designed to be coupled to the body unit 201 perpendicularly. Also, the rotatable unit 220 may be designed to be tilted with respect to the body unit 201.

FIG. 6B illustrates another embodiment of the pad unit 204. In FIG. 6B, the rotatable unit 220 may be designed to be coupled to the body unit 201 and tilted with respect to the body unit 201 without a support unit.

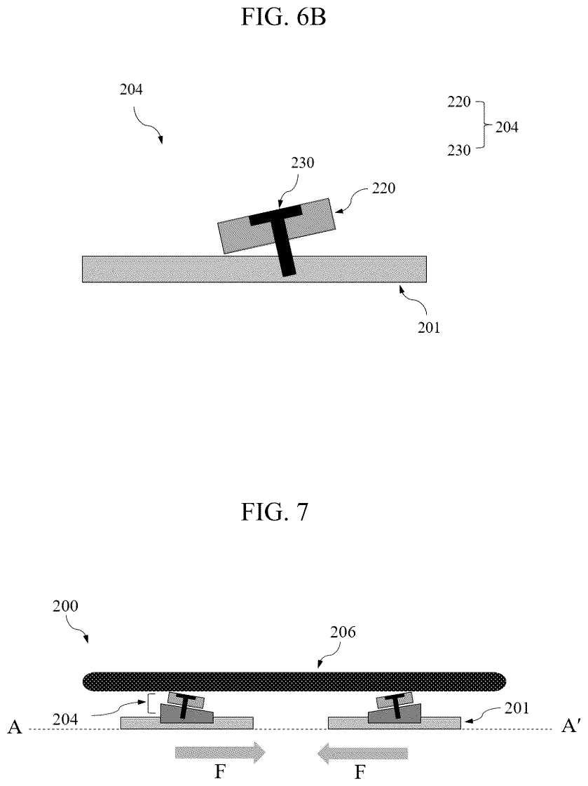

FIG. 7 illustrates a cross sectional view of the substrate transfer arm 200 along the cross-sectional line A-A′ of FIG. 3.

In FIG. 7, the pad unit 204 may be tilted toward a first direction F with respect to the body unit 201 of the substrate transfer arm 200. As illustrated in FIG. 7, a lower surface of the substrate 206 may contact the edge portion of the rotatable unit 220 of the pad unit 204 as shown in FIG. 3.

The edge portion of the rotatable unit 220 may be round as shown in FIG. 4. As a result, a friction between the lower surface of the substrate 206 and the edge portion of the rotatable unit 220 may be reduced accordingly. Therefore, the present disclosure may provide a technical benefit that the substrate may be prevented from sticking to the rotatable unit 220.

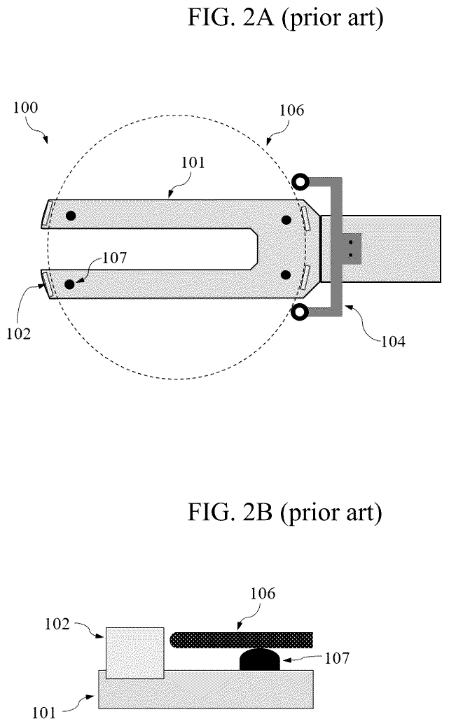

In the present disclosure, the rotatable unit 220 may not be fixed. As a result, the friction between the lower surface of the substrate 206 and the rotatable unit 220 may be reduced compared to the existing substrate transfer arm as shown in FIG. 2A and FIG. 2B. This may result in reduction of contaminants (i.e., as particles) accordingly.

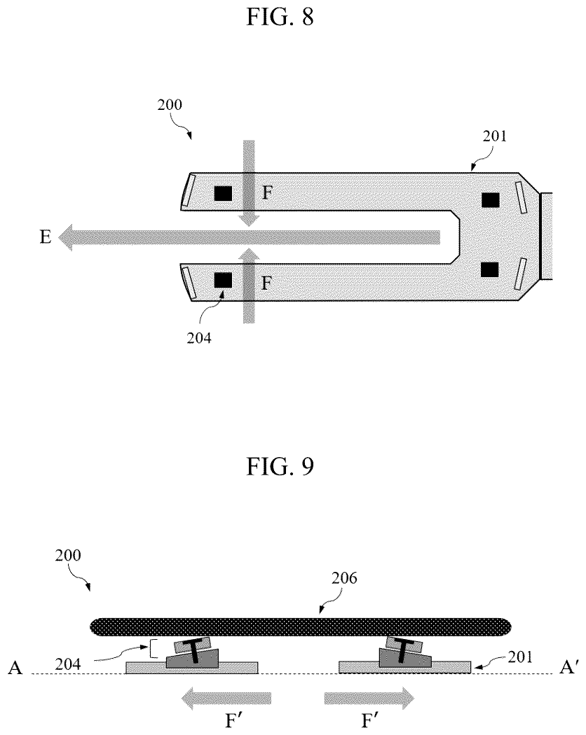

FIG. 8 illustrates the first direction F perpendicular to a moving direction E of the substrate transfer arm 200.

As illustrated in FIG. 7, the pad unit 204 may be tilted toward the first direction F. The first direction F may be perpendicular to the moving direction E of the substrate transfer arm 200. The moving direction E may be a direction in which the substrate transfer arm 200 moves to load or unload the substrate 206 mounted to or from a substrate support (not shown here).

FIG. 9 illustrates a cross sectional view of another embodiment of the substrate transfer arm 200 along the cross-sectional line A-A′ of FIG. 3.

In FIG. 9, the pad unit 204 may be tilted toward a second direction F′ different from the first direction F with respect to the body unit 201 of the substrate transfer arm 200. As illustrated in FIG. 9, a lower surface of the substrate 206 may contact the edge portion of the rotatable unit 220 of the pad unit 204 as denoted as C in FIG. 3.

Therefore, the present disclosure may provide a technical benefit that a contact face between the lower surface of the substrate 206 and the rotatable unit 220 may be minimized, reducing contaminants (i.e., particles). The present disclosure may also provide another technical benefit that the substrate sticking to the rotatable unit 220 may be prevented.

In the present disclosure, the rotatable unit 220 may not be fixed. As a result, a friction between the lower surface of the substrate 206 and the rotatable unit 220 may be reduced compared to the existing substrate transfer arm in which the pad unit may be fixed to the body unit as shown in FIG. 2A and FIG. 2B. This may result in reduction of contaminants (i.e., as particles) accordingly.

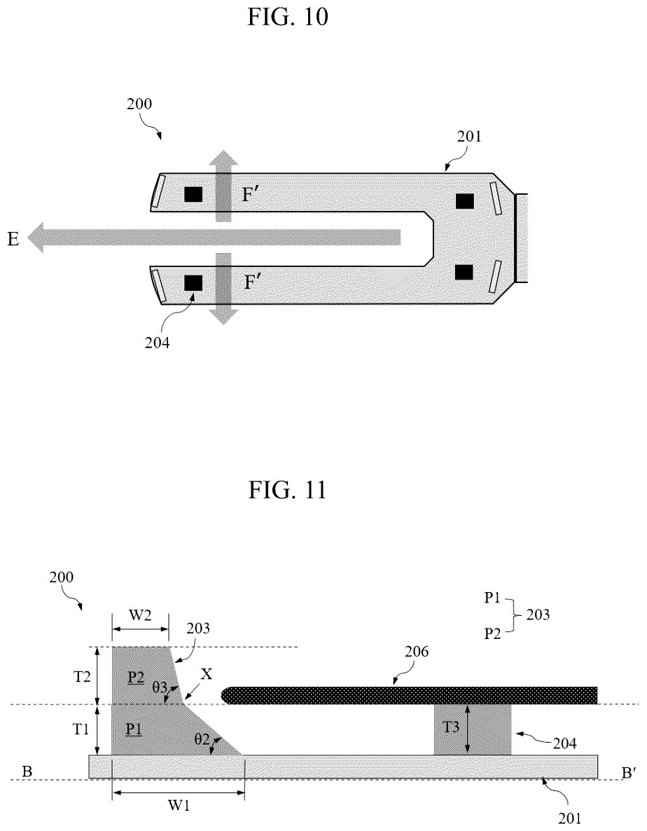

FIG. 10 illustrates the second direction F′ perpendicular to a moving direction E of the substrate transfer arm 200.

As illustrated in FIG. 9, the pad unit 204 may be tilted toward the second direction F′. The second direction F′ may be perpendicular to the moving direction E of the substrate transfer arm 200. The moving direction E may be a direction in which the substrate transfer arm 200 moves to load or unload the substrate 206 mounted thereon to or from a substrate support (not shown here).

FIG. 11 illustrates a cross-sectional view of an embodiment of the stopping unit 203 coupled to the body unit 201 of the substrate transfer arm 200 along the cross-sectional line B-B′ of FIG. 3.

In FIG. 11, the stopping unit 203 may comprise a first portion P1 and a second portion P2. The first portion P1 may have a height T1 and the second portion P2 may have a height T2.

The inner side of the second portion P2 may be tilted more than the inner side of the first portion P1 with respected to the body unit 201 (i.e., θ2<θ3). Therefore, when the substrate 206 slides forward on the pad unit 204, the stopping unit 203 may stop the substrate 206 from sliding over the stopping unit 203 more effectively on the second portion P2 than on the first portion P1. In other words, the stopping unit 203 may stop and retract the substrate 206 to the right position on the substrate transfer arm 200 more effectively on the second portion P2 than on the first portion P1.

To that end, a point (i.e., a point X in FIG. 11) in which the first portion P1 and the second portion P2 may meet may be located at the same height as the lower surface of the substrate 206 when sitting on the pad unit 204. Or the point X may be located lower than the lower surface of the substrate 206 when sitting on the pad unit 204. That is, the height T1 of the position X may be located at the height T3 of the pad unit 204 or below (i.e., T1≤T3).

In other words, the point X may be defined as a point in which a tilting angle θ2 of the first portion P1 may be changed to a tilting angle θ3 of the second portion P2, and the first portion P1 and the second portion P2 may meet at the point X. The point X may be located at the height of the upper surface of the pad unit 204 or below.

In the stopping unit 203, a horizontal cross-sectional width W1 of the lower surface of the first portion P1 may be wider than a horizontal cross-sectional width W2 of the upper surface of the second portion P2.

In the substrate transfer arm 200, an upper surface of the stopping unit 203 may be higher than an upper surface of the pad unit 204 (i.e., (T1+T2)>T3) to prevent the substrate 206 from coming off the substrate transfer arm 200.

FIG. 12 illustrates a cross-sectional view of another embodiment of the stopping unit 203 coupled to the body unit 201 of the substrate transfer arm 200 along the cross-sectional line B-B′ of FIG. 3.

In FIG. 12, the stopping unit 203 may comprise a first portion P1′ and a second portion P2′. The first portion P1′ may have a height T1′ and the second portion P2′ may have a height T2′.

In FIG. 12, an inner side of the first portion P1′ and an inner side of the second portion P2′ of the substrate stopping unit 203 may comprise curved surfaces.

The inner side of the second portion P2′ may be tilted more than the inner side of the first portion P1′ with respect to the body unit 201 (i.e., θ2′<θ3′). Therefore, when the substrate 206 slides forward moving on the pad unit 204, the stopping unit 203 may prevent the substrate 206 from sliding up the stopping unit 203 more effectively on the second portion P2′ than on the first portion P1′. In other words, the stopping unit 203 may stop and retract the substrate 206 to the right position on the substrate transfer arm 200 more effectively on the second portion P2′ than on the first portion P1′.

To that end, a point (i.e., a point X′ in FIG. 11) in which the first portion P1′ and the second portion P2′ meet may be located at the same height as the lower surface of the substrate 206 when sitting on the pad unit 204. Or the point X′ may be located lower than the lower surface of the substrate 206 when sitting on the pad unit 204. That is, the first height T1′ of the position X′ may be located at the height T3′ of the pad unit 204 or below (i.e., T1′≤T3′).

In other words, the point X′ in FIG. 12 may be defined as a point in which a tangential angle of the curved surface may be changed to a tangential angle θ3′, and the first portion P1′ and the second portion P2′ may meet at the point X′. The point X′ may be located at the height of the upper surface of the pad unit 204 or below.

In the stopping unit 203, a horizontal cross-sectional width W1′ of the lower surface of the first portion P1′ may be wider than a horizontal cross-sectional width W2′ of the upper surface of the second portion P2′.

In the substrate transfer arm 200, an upper surface of the stopping unit 203 may be higher than an upper surface of the pad unit 204 (i.e., (T1′+T2′)>T3′) to prevent the substrate 206 from coming off the substrate transfer arm 200.

As illustrated in FIG. 11 and FIG. 12, the tilted or curved surface of the inner side of the stopping unit 203 may prevent the substrate 206 from sliding up the stopping unit 203 more effectively and may assist the substrate 206 to sit on the right position on the substrate transfer arm 200.

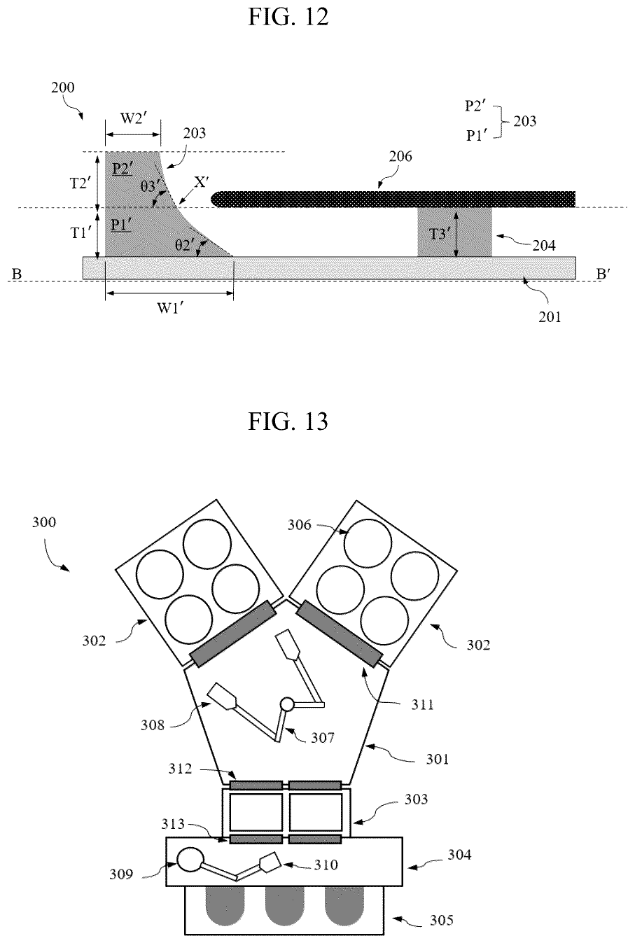

FIG. 13 illustrates a configuration of a substrate processing cluster tool.

In FIG. 13, the substrate processing cluster tool 300 may comprise a substrate handling chamber 301, a reaction chamber 302, a load lock chamber 303, a transport chamber 304, and a substrate storage stage 305.

The substrate handling chamber 301 may comprise a substrate handling device 307 (back end robot). The substrate handling device 307 may comprise a first substrate transfer arm 308 according to the present disclosure. The substrate handling device 307 may transfer a substrate from the load lock chamber 303 to the reaction chamber 302 via gate valves 311 and 312 or vice versa.

The first substrate transfer arm 308 may be configured according to the present disclosure. That is, the pad unit and the stopping unit of the present disclosure may be provided thereto.

The transport chamber 304 may comprise a substrate transport device 309 (front end robot). The substrate transport device 309 may comprise a second substrate transfer arm 310. The second substrate transfer arm 310 may be configured according to the present disclosure. That is, the pad unit and the stopping unit of the present disclosure may be provided thereto. The substrate transport device 309 may transfer a substrate from the substrate storage stage 305 to the load lock chamber 303 or vice versa. The transport chamber 304 may be an equipment front end module (EFEM) and the substrate storage stage 305 may be a front opening unified pod (FOUP).

The load lock chamber 303 may be located between the substrate handling chamber 301 and the transport chamber 304. In the load lock chamber 303, a substrate may be aligned or cooled after being processed at the reaction chamber 302.

The reaction chamber 302 may be provided with a reactor 306. In one embodiment, the reaction chamber 302 may be provided with a plurality of reactors 306.

A substrate may be transferred from the transport chamber 304 to the load lock chamber 303 via gate valves 313 or vice versa. The substrate handling chamber 301 and the reaction chamber 302 may be maintained at low pressure by vacuum pumps (not shown here).

1. A substrate transfer arm to mount a substrate comprising:
a body unit; and
a plurality of substrate mounting units coupled to the body unit, the substrate mounting units configured to load the substrate,
wherein each of the substrate mounting unit comprises a stopping unit and a pad unit coupled to the body unit, and the pad unit is tilted with respect to the body unit.

2. The substrate transfer arm of claim 1, wherein the pad unit is tilted between about 5° and about 30° with respect to the body unit.

3. The substrate transfer arm of claim 1, wherein the pad unit is tilted toward a first direction.

4. The substrate transfer arm of claim 3, wherein the first direction is perpendicular to a moving direction of the substrate transfer arm.

5. The substrate transfer arm of claim 1, wherein the pad unit is tilted toward a second direction different from the first direction.

6. The substrate transfer arm of claim 5, wherein the second direction is perpendicular to a moving direction of the substrate transfer arm.

7. The substrate transfer arm of claim 1, wherein the pad unit comprises:
a rotatable unit;
a support unit to support the rotatable unit; and
a fixing unit to couple the rotatable unit to the support unit,
wherein the rotatable unit is tilted with respect to the body unit.

8. The substrate transfer arm of claim 7, wherein the rotatable unit comprises a roller.

9. The substrate transfer arm of claim 8, wherein the roller is between about 0.8 cm and about 1.0 cm in diameter.

10. The substrate transfer arm of claim 8, wherein a surface roughness of the roller is between about Ra 0.4 and about Ra 3.2.

11. The substrate transfer arm of claim 8, wherein an edge of the roller is round.

12. The substrate transfer arm of claim 11, wherein a curvature of the edge of the roller is between about Φ8 and about Φ10.

13. The substrate transfer arm of claim 7, wherein the rotatable unit comprises at least one of cerazol, FFPM (Perfluorinated Elastomer), ceramic, glass carbon, or a mixture thereof.

14. The substrate transfer arm of claim 1, wherein an upper surface of the stopping unit is higher than an upper surface of the pad unit.

15. The substrate transfer arm of claim 1, wherein the stopping unit comprises a first portion and a second portion.

16. The substrate transfer arm of claim 15, wherein an inner side of the second portion is tilted more than an inner side of the first portion with respected to the body unit.

17. The substrate transfer arm of claim 16, wherein the stopping unit further comprises a point in which the first portion and the second portion meet is located at a height of an upper surface of the pad unit or below.

18. The substrate transfer arm of claim 15, wherein an inner side of the first portion and an inner side of the second portion comprise curved surfaces.

19. The substrate transfer arm of claim 1, further comprising a clamp unit to clamp the substrate.

20. A substrate processing cluster tool comprising:
a substrate handling chamber, the substrate handling chamber comprises a substrate handling device;
a reaction chamber;
a load lock chamber;
a transport chamber, the transport chamber comprises a substrate transport device; and
a substrate storage stage,
wherein the substrate transport device comprises a substrate transfer arm, and the substrate transfer arm comprises a body unit, a pad unit, a stopping unit and a clamp unit, and the pad unit is tilted with respect to the body unit.
